(19) United States
(12) Patent Application Publication
(10) Pub. No.: US 2024/0200944 A1
(43) Pub. Date: Jun. 20, 2024

(54) MICROMECHANICAL ROTATION RATE SENSOR COMPRISING A SENSOR ELEMENT AND A METHOD FOR OPERATING A MICROMECHANICAL ROTATION RATE SENSOR COMPRISING A SENSOR ELEMENT

(71) Applicant: Robert Bosch GmbH, Stuttgart (DE)

(72) Inventors: Filippo David, Milano (IT); Gabriele Cazzaniga, Rosate MI (IT); Giuseppe Sciortino, Mailand (IT); Stefano Sala, Mailand (IT); Thorsten Balslink, Kirchentellinsfurt (DE)

(21) Appl. No.: 18/493,793

(22) Filed: Oct. 24, 2023

(30) Foreign Application Priority Data
Dec. 19, 2022 (DE) 10 2022 213 827.9

(51) Int. Cl. G01C 19/5712; G01C 19/5762

(52) U.S. Cl. CPC G01C 19/5712; G01C 19/5762

(57) ABSTRACT

A micromechanical rotation rate sensor with a sensor element. The micromechanical rotation rate sensor including a drive device for driving an oscillation of the sensor element and an acquisition device for acquiring a measurement signal. The acquisition device includes a first and second electrode structure for acquiring a mechanical deflection or a force effect of the sensor element parallel to an acquisition direction provided substantially perpendicular to the drive direction. A variable capacitance may be formed between the sensor element and the first electrode structure and between the sensor element and the second electrode structure. The acquisition device is provided for differential acquisition of the variable capacitances, which each comprise a static capacitance component and a dynamic capacitance component provided for the opposite variation. The micromechanical rotation rate sensor is configured such that the static capacitance component is ascertained by a variation of the predetermined voltage.

### CROSS REFERENCE

The present application claims the benefit under 35 U.S.C. § 119 of German Patent Application No. DE 10 2022 213 827.9 filed on Dec. 19, 2022, which is expressly incorporated herein by reference in its entirety.

### FIELD

The present invention relates to a micromechanical rotation rate sensor comprising a sensor element.

### BACKGROUND INFORMATION

Micromechanical rotation rate sensors acquire rotations or rotation rates about one or more axes by evaluating deflections of or force effects on a mechanical structure or multiple mechanical structures or on one or more sensor elements, usually by means of capacitive acquisition devices. Specifically, this acquisition is carried out by a plurality of capacitors or capacitor arrangements which are formed by electrode structures and possibly a part or parts of the sensor element or sensor elements, wherein the respective relevant distance, for example the electrode distance, affects the capacitance or the capacitance value of the capacitor arrangements, so that the (relative) position of the mechanical structure or the sensor element or the sensor elements, in particular to substrate-fixed electrode structures, can be determined. Such an acquisition device is thus able to detect a change in the electrode distance caused by a movement of the mechanical structure or the sensor element based on a change in the capacitance. This is proportional (in the linear range) to the external physical stimulus or the deflection of the sensor element.

The acquisition devices or electrode structures are typically implemented either in the form of parallel plates or in the form of comb electrodes. The former are often used for comparatively small deflections, because these acquisition devices or electrode structures provide a comparatively high sensitivity.

The latter are used for larger deflections, such as those that occur when the sensor element is being driven. The aforementioned plate capacitors are typically used for acquisition in the detection direction (i.e., usually perpendicular to the drive direction). The advantage of this solution is a higher sensitivity, but at the expense of the sensitivity being dependent on the distance between the plates of the capacitor arrangement under consideration. Such a dependence leads to a strong nonlinearity in the response behavior, which can usually be (first-order) compensated by differentially reading out two plate capacitors with opposite changes in the plate spacing. Even if such a differential readout eliminates most of the nonlinearity, a common mode change in the distance or plate spacing (i.e., the plate spacings on both sides of the sensor element or for multiple sensor elements change with the same sign) leads to a change in the sensitivity and generally to a performance degradation. Such a common mode change in the distance or plate spacing on both sides of the sensor element can be caused by undesirable effects such as deformation of the substrate due to temperature or soldering.

### SUMMARY

It is an object of the present invention to provide a micromechanical sensor system comprising a sensor element, with which it is possible, on the one hand, to ensure a high sensitivity of a capacitive acquisition device and, on the other hand, realize efficient, in particular energy-efficient, operation.

The micromechanical rotation rate sensor according to the present invention with a sensor element according to the present has the advantage over the related art that, in addition to the acquisition of the dynamic capacitance component of the variable capacitances (differential capacitive acquisition), the static capacitance component of the variable capacitances (rectified capacitive acquisition/common mode) can be acquired as well.

This further acquisition makes it possible to compensate interference effects that cannot be compensated on the basis of the differential evaluation in a more targeted manner, in particular in digital form. Interference effects, for example triggered by temperature changes or soldering effects, can thus be better compensated, and characterizing parameters of the micromechanical rotation rate sensor, such as the sensitivity and the phase shift of the acquisition device and/or the predetermined voltage to which the sensor element (mechanical structure) is subjected, can be adjusted more efficiently. The micromechanical rotation rate sensor can thus advantageously be used effectively and energy-efficiently.

Advantageous embodiments and further developments of the present invention will emerge from the disclosure herein.

According to one advantageous embodiment of the present invention, it is provided that the micromechanical rotation rate sensor is configured in such a way that it can be operated in a test operating mode and in an operational operating mode, wherein, during the test operating mode, the sensor element is acted upon according to the variation of the predetermined voltage, and wherein, during the operational operating mode, the sensor element is statically subjected to the predetermined voltage, wherein the micromechanical rotation rate sensor is in particular provided to be operated continuously for a maximum of 2 seconds in the test operating mode, in particular operated continuously for a maximum of 1 second, in particular continuously for a maximum of 500 ms, in particular continuously for a maximum of 50 ms in the test operating mode. The micromechanical rotation rate sensor can thus advantageously be operated energy-efficiently in the operational operating mode, which covers a comparatively large time interval during operation of the micromechanical rotation rate sensor. It is in particular possible, in the comparatively short time interval of the test operating mode, to ascertain a compensation value which can then be used in the operational operating mode for, in particular digital, compensation of the interference effects.

According to one advantageous embodiment of the present invention, it is provided that a further acquisition device for acquiring a mechanical deflection of the sensor element parallel to the drive device is provided, wherein the further acquisition device comprises a third and a fourth electrode structure, wherein the sensor element is disposed along the acquisition direction relative to the third electrode structure and relative to the fourth electrode structure in such a way that a further variable capacitance is formed between the sensor element and the third electrode structure and between the sensor element and the fourth electrode structure, wherein the further acquisition device is provided for differential acquisition of the further variable capacitances, wherein the further variable capacitances likewise each comprise a further static capacitance component and a further dynamic capacitance component provided for the opposite variation, wherein the micromechanical rotation rate sensor is configured such that the further static capacitance component is ascertained by means of a variation of the predetermined voltage. It is thus advantageously possible to acquire the static capacitance component of the variable capacitance in the drive direction as well, and to compensate interference effects that cannot be compensated on the basis of the differential evaluation. Thus, precise and efficient, in particular energy-efficient, acquisition in the drive direction can advantageously be carried out.

According to one advantageous embodiment of the present invention, it is provided that the sensor element is disposed between the first electrode structure and the second electrode structure and/or between the third electrode structure and the fourth electrode structure. One advantage of this embodiment is that it is in particular possible to design/produce/manufacture the micromechanical rotation rate sensor comprising a sensor element in a particularly effective and compact manner and thus ensure advantageous energy-efficient operation.

According to one advantageous embodiment of the present invention, it is provided that the acquisition device for the variable capacitances comprises at least one operational amplifier for measuring the static capacitance component of the variable capacitance and/or the further acquisition device for the further variable capacitances comprises at least one further operational amplifier for measuring the further static capacitance component of the further variable capacitance. It is thus advantageously possible to repurpose a (further) already existing acquisition structure for ascertaining the dynamic capacitance component of the variable capacitance and in particular to filter out the static component of the variable capacitances by applying a reference voltage (to one of the two inputs of the operational amplifier).

According to one advantageous embodiment of the present invention, it is provided that the variation of the predetermined voltage corresponds to a square wave voltage. It is thus advantageously possible to ensure efficient, in particular energy-efficient acquisition of the static component of the variable capacitances.

According to one advantageous embodiment of the present invention, it is provided that the micromechanical rotation rate sensor is operated in test operating mode with or without operation of the drive device, during production and/or in operational use, temporarily for calibration purposes and/or continuously with a predetermined periodicity, in particular every 100 seconds, in particular every 10 seconds. One advantage of this embodiment is that it is in particular possible to operate the micromechanical rotation rate sensor in an energy-efficient manner.

A further subject matter of the present invention is a method for operating a micromechanical sensor system with a sensor element.

The method according to the present invention for operating a micromechanical sensor system comprising a rotation rate sensor proves to be advantageous over the related art in that the acquisition of the static capacitance component of the variable capacitance can be used to counteract interference effects. This in particular makes it possible to correct interference effects that cannot be compensated using the dynamic capacitance component of the variable capacitance and are triggered, for example, by temperature changes or soldering effects. According to the present invention, characteristic parameters of the acquisition device, for example its sensitivity and phase shift, and/or the predetermined voltage to which the sensor element is subjected, can be adjusted more effectively and thus ensure energy-efficient operation.

The advantages and configurations described in connection with the embodiments of the micromechanical sensor system according to the present invention or the sensor element apply likewise to the method for operating a micromechanical sensor system with a sensor element according to the present invention.

According to an example embodiment of the present invention, it is preferably possible that the micromechanical rotation rate sensor comprising a sensor element can comprise circuit means (i.e., a circuit) and/or be connected to circuit means, wherein the micromechanical rotation rate sensor and/or the circuit means are configured to carry out a method according to an embodiment of the present invention.

Embodiment examples of the present invention are shown in the figures and explained in more detail in the following description.

### BRIEF DESCRIPTION OF THE DRAWINGS

FIG. 1A and FIG. 1B each show a schematic diagram of a part of an acquisition device or relatively movable electrode structures in the form of comb electrodes (FIG. 1A) and in the form of parallel plate electrodes (FIG. 1B), according to an example embodiment of the present invention.

FIG. 2 shows a schematic diagram of a part of an acquisition device in the form of a parallel plate electrode arrangement for differential readout or acquisition the dynamic capacitance component of the variable capacitances, according to an example embodiment of the present invention.

FIG. 3 shows a schematic basic circuit diagram of the acquisition device including an operational amplifier for differential capacitance readout and/or readout of the dynamic capacitance component of the variable capacitances, according to the related art.

FIG. 4 shows a schematic basic circuit diagram of the extension of the acquisition device as shown in FIG. 3 by an operational amplifier for reading out the static capacitance component of the variable capacitances, according to an example embodiment of the present invention.

### DETAILED DESCRIPTION OF EXAMPLE EMBODIMENTS

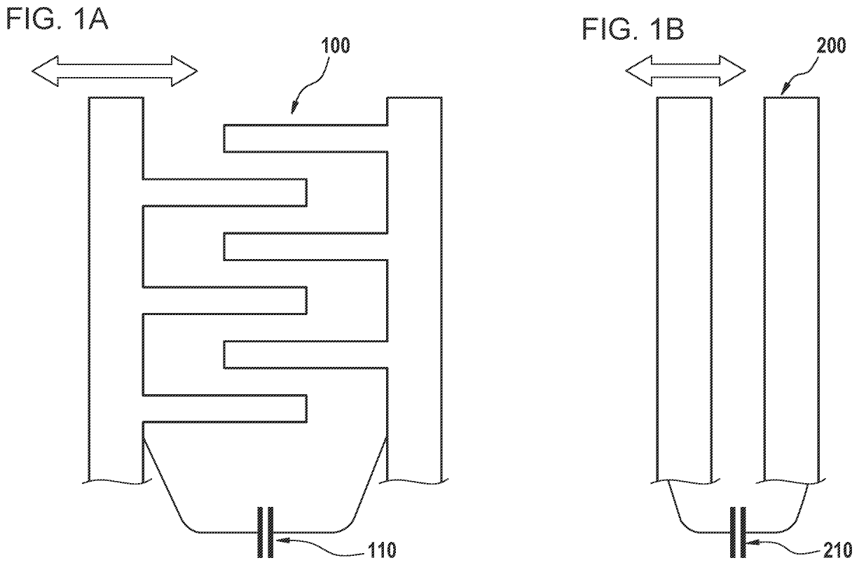

FIG. 1A and FIG. 1B each show a schematic diagram of a part of an acquisition device or a unilaterally movable electrode structure according to the present invention. FIG. 1A shows a unilaterally movable or relatively movable comb electrode structure 100, while FIG. 1B shows a unilaterally movable electrode structure in the form of parallel plates 200. Both cases of the electrode arrangement result in a capacitance value 110 and 210, which changes in particular due to a relative movement of the respective electrode structure 100 and 200. According to the present invention, it is provided that the acquisition of the capacitance 110 of the comb electrode structure 100 is preferably used to detect large deflections—typically (but not necessarily) used in the drive direction. For small deflections, detection is preferably carried out using parallel plates 200—typically (but not necessarily) used in the detection direction.

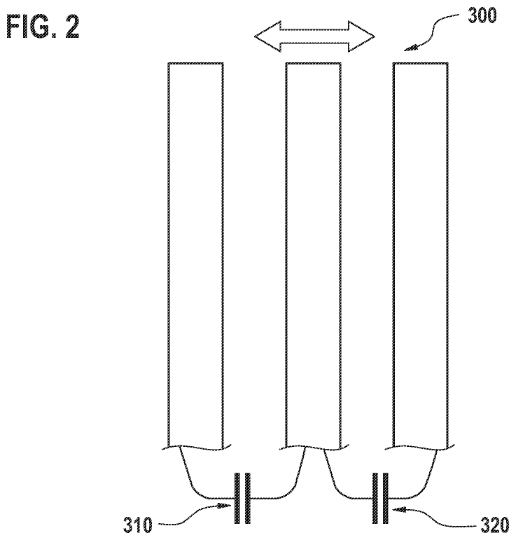

FIG. 2 is a schematic diagram of a part of an acquisition device or arrangement 300 of two outer rigid electrodes and the sensor element in the center. The arrangement 300 illustrates the principle of differential measurement of the capacitance or the capacitance value of the electrode arrangement according to the present invention. The electrodes in the arrangement 300 are moreover shown as parallel plates. For deflections of the sensor element, the two shown variable capacitances 310 and 320 result in not only a static capacitance component but also a dynamic capacitance component. Small deflections in particular result in the same static capacitance component as well as the same dynamic capacitance component.

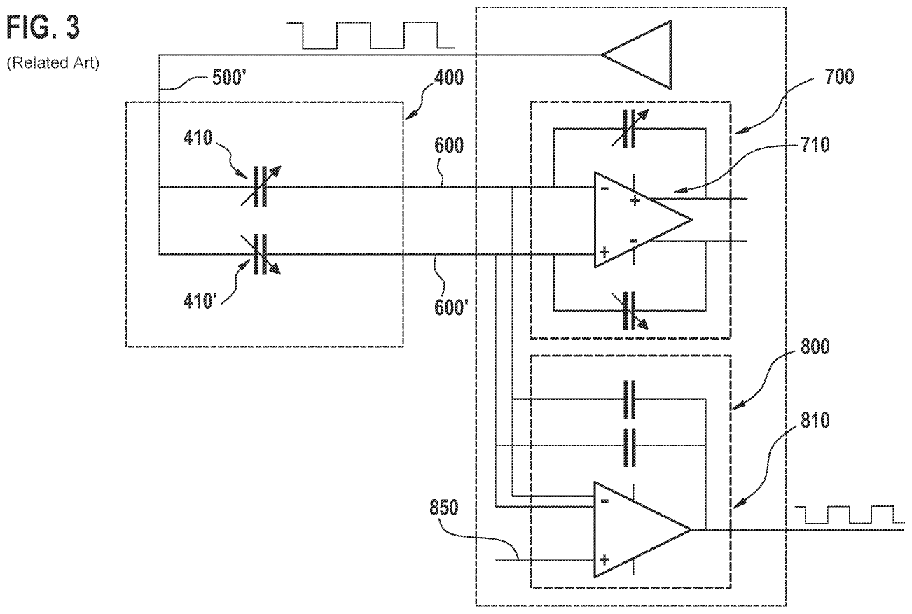

FIG. 3 shows a basic circuit diagram of the acquisition device including an operational amplifier for determining the dynamic capacitance component 710 of the variable capacitances 410 and 410′ (differential readout) in accordance with the related art. The capacitances 410 and 410′ correspond to the capacitances 310 and 320 according to FIG. 2. The sensor element of the micromechanical rotation rate sensor 400 is furthermore statically subjected to a predetermined voltage 500. The two considered capacitor arrangements of the variable capacitances 410 and 410′ are connected (via lines 600 and 600′) to an operational amplifier 700. The operational amplifier 700 is used to differentially determine the two variable capacitances 410 and 410′ and thus acquire the dynamic capacitance component 710.

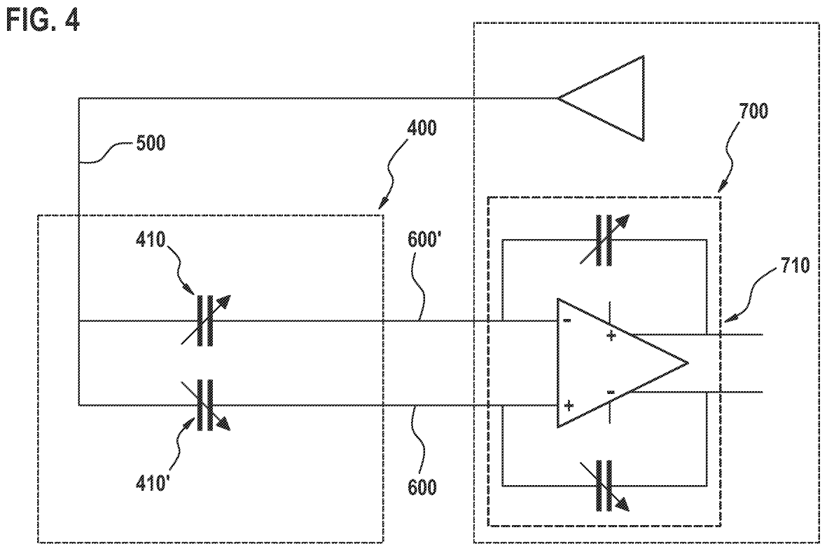

FIG. 4 shows a basic circuit diagram of the acquisition device according to an embodiment of the present invention. In addition to the operational amplifier 700, a further operational amplifier 800 is provided for reading out the static capacitance component 810 and is in particular connected in parallel with the operational amplifier 700. The sensor element of the micromechanical rotation rate sensor 400 is likewise subjected to a predetermined voltage 500′; for acquiring or determining the static capacitance component 810, this voltage 500′ is provided or implemented as a varying predetermined voltage 500′. The two considered capacitor arrangements of the variable capacitances 410 and 410′ are again connected (via lines 600 and 600′) to the operational amplifiers 700 and 800. The two variable capacitances 410 and 410′ are differentially read out via the operational amplifier 700, thus determining the dynamic capacitance component 710 of the variable capacitances 410 and 410′. As long as the predetermined voltage 500′ is a varying predetermined voltage, the static capacitance component 810 of the variable capacitances 410 and 410′ is furthermore determined via the operational amplifier 800 using a reference voltage 850.

The acquisition device according to the embodiment of the present invention is intended to be operated in either a test operating mode or an operational operating mode. During the test operating mode, the sensor element of the micromechanical rotation rate sensor 400 is subjected to the varying predetermined voltage 500, so that the static capacitance component 810 can always be determined and, if necessary, the dynamic capacitance component 710 of the variable capacitances 410 and 410′ is determined as well (in particular if the drive of the rotation rate sensor is activated). In the operational operating mode, the sensor element of the micromechanical rotation rate sensor 400 is likewise subjected to the predetermined voltage 500′, but in this case this predetermined voltage 500′ is a static voltage 500′, so that only the dynamic capacitance component 710 is determined. In the operational operating mode, the operational amplifier 800 can in particular preferably be set to an idle state and/or energy-saving state.

According to the present invention, it is furthermore in particular provided that the micromechanical rotation rate sensor 400 is operated continuously for a maximum of 2 seconds in the test operating mode, in particular continuously for a maximum of 1 second, in particular continuously for a maximum of 500 ms, in particular continuously for a maximum of 50 ms.

The micromechanical rotation rate sensor 400 can also be operated in test operating mode with or without operation of the drive device, during production and/or in operational use, temporarily for calibration purposes and/or continuously with a predetermined periodicity, in particular every 100 seconds, in particular every 10 seconds. In the case of operation without drive, only the static capacitance component 810 is determined. In the test operating mode, the operational amplifier 700 can in particular preferably be set to an idle state and/or energy-saving state.

According to the present invention, the static capacitance component 810 can be converted into a digital signal by means of suitable signal processing, for example demodulation, and used according to the present invention for efficient compensation of interference effects.

Example applications for such a device are preferably gyroscopes and acceleration sensors. For both sensor types, interference effects can be identified in the detection direction. These could be effectively compensated using the abovementioned demodulation, thus making the functioning of the sensors more efficient.

According to the present invention, it is moreover also possible to detect and compensate deformations of the mechanical structure. These deformations, such as those caused by temperature changes or soldering effects, cannot be compensated by means of a differential readout 710, because this type of deformation is largely hidden in the difference of the differential detection 710 since its change is in the same direction (i.e. change in the static capacitance component 810).

Analog acquisition by a further acquisition device parallel to the drive device can be provided as well, but this is not shown in FIG. 4. A further static capacitance component and a further dynamic capacitance component can be determined by the further acquisition device by varying the predetermined voltage 500′.

What is claimed is:

1. A micromechanical rotation rate sensor, comprising:
a sensor element;
a drive device configured to drive an oscillation of the sensor element along a drive direction; and
an acquisition device configured to acquire a measurement signal generated using the sensor element, wherein the acquisition device includes a first electrode structure and a second electrode structure configured to acquire a mechanical deflection or a force effect of the sensor element parallel to an acquisition direction provided substantially perpendicular to the drive direction;
wherein the sensor element is subjected to a predetermined voltage and both the first electrode structure and the second electrode structure are disposed along the acquisition direction relative to the sensor element in such a way that a variable capacitance is formed between the sensor element and the first electrode structure and between the sensor element and the second electrode structure, wherein the acquisition device is configured for differential acquisition of the variable capacitances, wherein the variable capacitances each include a static capacitance component and a dynamic capacitance component provided for an opposite variation;
wherein the micromechanical rotation rate sensor is configured such that the static capacitance component is ascertained using a variation of the predetermined voltage.

2. The micromechanical rotation rate sensor according to claim 1, wherein the micromechanical rotation rate sensor is configured in such a way that it can be operated in a test operating mode and in an operational operating mode, wherein, during the test operating mode, the sensor element is acted upon according to the variation of the predetermined voltage, and wherein, during the operational operating mode, the sensor element is statically subjected to the predetermined voltage, wherein the micromechanical rotation rate sensor is configured to be operated continuously for a maximum of 2 seconds in the test operating mode.

3. The micromechanical rotation rate sensor according to claim 2, wherein the micromechanical rotation rate sensor is configured to be operated continuously for a maximum of 1 second.

4. The micromechanical rotation rate sensor according to claim 1, further comprising:
a further acquisition device configured to acquire a mechanical deflection of the sensor element parallel to the drive device, wherein the further acquisition device includes a third electrode structure and a fourth electrode structure,
wherein the sensor element is disposed along the acquisition direction relative to the third electrode structure and relative to the fourth electrode structure in such a way that a further variable capacitance is formed between the sensor element and the third electrode structure and between the sensor element and the fourth electrode structure;
wherein the further acquisition device is configured for differential acquisition of the further variable capacitances, wherein the further variable capacitances each include a further static capacitance component and a further dynamic capacitance component provided for the opposite variation, wherein the micromechanical rotation rate sensor is configured such that the further static capacitance component is ascertained using a variation of the predetermined voltage.

5. The micromechanical rotation rate sensor according to claim 4, wherein the sensor element is disposed between the first electrode structure and the second electrode structure and/or between the third electrode structure and the fourth electrode structure.

6. The micromechanical rotation rate sensor according to claim 4, wherein: (i) the acquisition device for the variable capacitances includes at least one operational amplifier configured to measure the static capacitance component of the variable capacitance, and/or (ii) the further acquisition device for the further variable capacitances includes at least one further operational amplifier configured to measures the further static capacitance component of the further variable capacitance.

7. The micromechanical rotation rate sensor according to claim 1, wherein the variation of the predetermined voltage corresponds to a square wave voltage.

8. The micromechanical rotation rate sensor according to claim 2, wherein the micromechanical rotation rate sensor is operated in the test operating mode with or without operation of the drive device, during production and/or in operational use, temporarily for calibration purposes and/or continuously with a predetermined periodicity.

9. A method for operating a micromechanical rotation rate sensor with a sensor element, wherein the micromechanical rotation rate sensor includes a drive device configured to drive an oscillation of the sensor element along a drive direction and an acquisition device configured to acquire a measurement signal generated using the sensor element, wherein the acquisition device includes a first electrode structure and a second electrode structure configured to acquire a mechanical deflection or a force effect of the sensor element parallel to an acquisition direction provided substantially perpendicular to the drive direction, wherein the sensor element is subjected to a predetermined voltage, and both the first electrode structure and the second electrode structure are disposed along the acquisition direction relative to the sensor element in such a way that a variable capacitance is formed between the sensor element and the first electrode structure and between the sensor element and the second electrode structure, wherein the acquisition device is configured for differential acquisition of the variable capacitances, wherein the variable capacitances each including a static capacitance component and a dynamic capacitance component provided for an opposite variation, wherein the micromechanical rotation rate sensor is configured such that it can be operated in a test operating mode and in an operational operating mode, wherein the method comprises:
operating the micromechanical rotation rate sensor in the test operating mode, wherein, during the test operating mode, the sensor element is acted upon by a variation of the predetermined voltage; and
operating the micromechanical rotation rate sensor in the operational operating mode, wherein, during the operational operating mode, the sensor element is statically subjected to the predetermined voltage;
ascertaining the static capacitance component using the variation of the predetermined voltage, wherein the test operating mode is used to ascertain the static capacitance component at different times or continuously in order to detect changes in the static capacitance component; and
adjusting, using the detected changes in the static capacitance component, further parameters of the rotation rate sensor including its sensitivity and/or a phase shift of the acquisition device and/or the predetermined voltage to which the sensor element is subjected.
